(19) United States
(12) Patent Application Publication
(10) Pub. No.: US 2026/0208296 A1
(43) Pub. Date: Jul. 23, 2026

(54) MANUFACTURING METHOD FOR COMPOSITE SUBSTRATE

(71) Applicant: NGK INSULATORS, LTD., Nagoya-shi (JP)

(72) Inventors: Shoichiro YAMAGUCHI, Ichinomiya-shi (JP); Yuki NOMOTO, Nagoya -shi (JP); Junji SAKAI, Gifu-shi (JP); Naoki FUJITA, Nagoya -shi (JP)

(21) Appl. No.: 19/571,612

(22) Filed: Mar. 19, 2026

Related U.S. Application Data
(63) Continuation of application No. PCT/JP2024/033820, filed on Sep. 24, 2024.

(30) Foreign Application Priority Data
Sep. 26, 2023 (JP) 2023-164048

(51) Int. Cl. B23K 26/21; H10N 30/073

(52) U.S. Cl. CPC B23K 26/21; H10N 30/073

(57) ABSTRACT

A manufacturing method for a composite substrate includes a step of forming an intermediate layer on a support substrate, a step of irradiating, with a fast atom beam, each of a surface of a piezoelectric material substrate and a surface of the intermediate layer formed on the support substrate, a step of further irradiating the surface of the piezoelectric material substrate with the fast atom beam, and forming a sputtered film containing the material of the piezoelectric material substrate on the surface of the intermediate layer, a step of obtaining a bonded body having a waveguide substrate by bonding the piezoelectric material substrate and the intermediate layer on which the sputtered film is formed, and a step of irradiating this bonded body with laser light in a surface direction of the composite substrate, wherein the composite substrate is formed using the bonded body irradiated with the laser light.

### CROSS-REFERENCE TO RELATED APPLICATION

This application is a continuation application of PCT/JP2024/033820, filed on September 24, 2024, which claims the benefit of priority of Japanese application JP2023-164048, filed on September 26, 2023, the entire contents of which are incorporated herein by reference.

### TECHNICAL FIELD

The present invention relates to a manufacturing method for a composite substrate.

### DESCRIPTION OF RELATED ART

Conventionally, a composite substrate is known, which is formed by bonding a piezoelectric substrate made of a material such as lithium niobate (LN, LiNbO₃) or lithium tantalate (LT, LiTaO₃) and a support substrate made of a material such as Si, and that is used for surface acoustic wave devices and the like. A method is known as a fabrication method for such a composite substrate in which an activation treatment is performed by irradiating respective bonding surfaces of the piezoelectric substrate and the support substrate with a fast atom beam (FAB), and subsequently directly bonding these bonding surfaces to each other. However, this method has a problem in that bonding strength between the substrates is low and that the substrates may peel off in post-bonding processing steps.

Accordingly, a technique disclosed in Patent Literature 1 (International Publication No. WO 2017/163722) is known as a means to solve the above problems. Patent Literature 1 discloses a method of forming a silicon oxide (SiO₂) film as an intermediate layer on a support substrate, further forming a bonding layer made of a material such as silicon nitride (Si₃N₄) on this film, and directly bonding a piezoelectric substrate and the bonding layer. According to this method, bonding strength between the piezoelectric substrate and the support substrate is enhanced, and peeling after bonding is prevented.

In a composite substrate having the structure of Patent Literature 1, a bonding layer made of Si₃N₄ is provided. However, when using a piezoelectric material substrate such as LN (LiNbO₃) or LT (LiTaO₃) as a functional layer, a composite substrate in which a bonding layer is not provided is desired from the viewpoint of energy confinement (light, elastic waves, etc.).

In order to obtain a composite substrate in which a bonding layer is not provided, sufficient bonding strength cannot be obtained even when bonding the piezoelectric substrate and the support substrate on which the silicon oxide intermediate layer is formed in a manufacturing step of the composite substrate, thus requiring improvement. The same applies when the piezoelectric substrate and the support substrate are directly bonded. Therefore, there is a problem with the bonding strength between the intermediate layer provided on the support substrate or the support substrate itself and the piezoelectric material substrate made of LiNbO₃ or LiTaO₃.

The present invention has been made in view of the above circumstances, and a principal object thereof is to realize a manufacturing method for a composite substrate that enhances bonding strength between an intermediate layer provided on a support substrate or the support substrate itself and a piezoelectric material substrate, and that enables the composite substrate to exhibit favorable optical propagation characteristics.

### SUMMARY OF THE INVENTION

A manufacturing method for a composite substrate according to a first aspect of the present invention includes: a step of forming an intermediate layer containing at least one of SiO₂, MgF₂, or CaF₂ on a support substrate; a step of irradiating, with a fast atom beam, each of a surface of a piezoelectric material substrate formed using LN or LT as a material and a surface of the intermediate layer formed on the support substrate; a step of further irradiating the surface of the piezoelectric material substrate with the fast atom beam, and forming a sputtered film containing the material of the piezoelectric material substrate on the surface of the intermediate layer; a step of obtaining a bonded body by bonding the piezoelectric material substrate and the intermediate layer on which the sputtered film is formed; and a step of irradiating the bonded body with laser light in a surface direction of the composite substrate, wherein the composite substrate is formed using the bonded body irradiated with the laser light. A manufacturing method for a composite substrate according to a second aspect of the present invention includes: a step of irradiating, with a fast atom beam, each of a surface of a piezoelectric material substrate formed using LN or LT as a material and a surface of a support substrate containing SiO₂, MgF₂, or CaF₂; a step of further irradiating the surface of the piezoelectric material substrate with the fast atom beam, and forming a sputtered film made of the material of the piezoelectric material substrate on the surface of the support substrate; a step of obtaining a bonded body by bonding the piezoelectric material substrate and the support substrate on which the sputtered film is formed; and a step of irradiating the bonded body with laser light in a surface direction of the composite substrate, wherein the composite substrate is formed using the bonded body irradiated with the laser light.

According to the present invention, it is possible to realize a manufacturing method for a composite substrate that enhances bonding strength between an intermediate layer provided on a support substrate or the support substrate itself and a piezoelectric material substrate, and that enables the composite substrate to exhibit favorable optical propagation characteristics.

### BRIEF DESCRIPTION OF THE DRAWINGS

FIGS. 1A and 1B are diagrams showing a schematic configuration of a composite substrate according to a first embodiment of the present invention.

FIGS. 2A, 2B, 2C and 2D are diagrams showing an example of manufacturing steps of the composite substrate according to the first embodiment of the present invention.

FIGS. 3E, 3F and 3G are diagrams showing an example of the manufacturing steps of the composite substrate according to the first embodiment of the present invention.

FIGS. 4H and 4I are diagrams showing an example of the manufacturing steps of the composite substrate according to the first embodiment of the present invention.

FIGS. 5A and 5B are diagrams showing a schematic configuration of a composite substrate according to a second embodiment of the present invention.

FIGS. 6A, 6B and 6C are diagrams showing an example of manufacturing steps of the composite substrate according to the second embodiment of the present invention.

FIGS. 7D, 7E and 7F are diagrams showing an example of the manufacturing steps of the composite substrate according to the second embodiment of the present invention.

FIGS. 8G and 8H are diagrams showing an example of the manufacturing steps of the composite substrate according to the second embodiment of the present invention.

FIG. 9 is a diagram showing a characteristics evaluation system of the composite substrate.

### DESCRIPTION OF PREFERRED EMBODIMENTS

Hereinafter, embodiments of the present invention are described with reference to the drawings, but the present invention is not limited to these embodiments. The drawings may schematically represent widths, thicknesses, shapes, and the like of respective parts, relative to those of the embodiments in order to clarify the description; however, the drawings are merely examples and are not intended to limit the interpretation of the present invention.

### First Embodiment

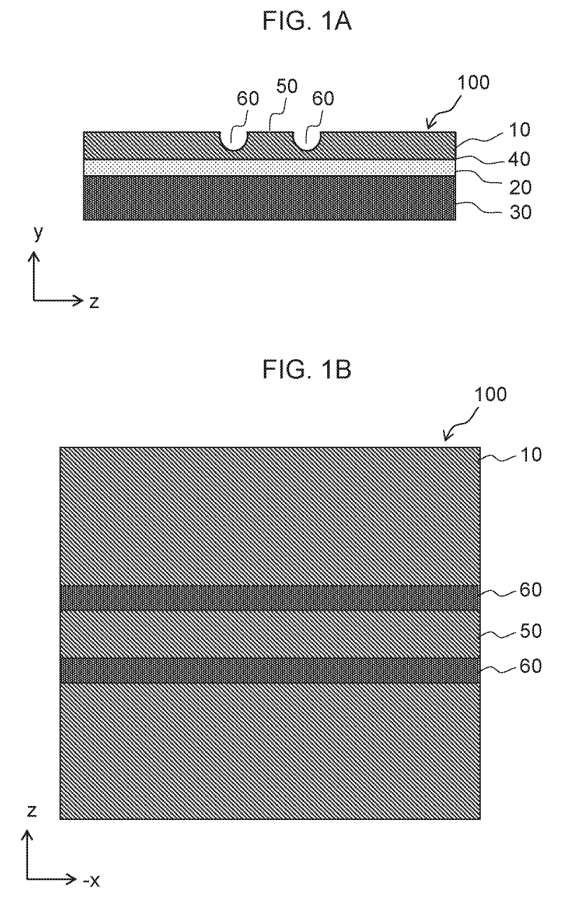

FIGS. 1A and 1B are diagrams showing a schematic configuration of a composite substrate according to a first embodiment of the present invention. A composite substrate 100 in the present embodiment is used, for example, as an optical element constituting an optical waveguide. The composite substrate 100 has a structure in which a piezoelectric material substrate is bonded to a support substrate 30 via an intermediate layer 20. FIG. 1A is a schematic cross-sectional view of the composite substrate 100, and FIG. 1B is a schematic plan view of the composite substrate 100. The x-, y-, and z-coordinate axes shown in FIGS. 1A and 1B are defined in accordance with the crystal axes of a waveguide substrate 10.

In the first embodiment, the piezoelectric material substrate is the waveguide substrate 10 including an optical waveguide, and a groove 60 that extends linearly in the crystal x-axis direction of the waveguide substrate 10 is formed, by linearly removing a surface of the waveguide substrate 10 to a predetermined width by dry etching, dicing, laser processing, or the like. This groove 60 is provided at two locations on the surface of the waveguide substrate 10 with a certain spacing therebetween. Thus, a ridge portion 50 having a trapezoidal cross section is formed in a portion sandwiched between the pair of mutually parallel grooves 60. This ridge portion 50 is used as the optical waveguide.

For example, a piezoelectric material such as lithium niobate (LiNbO₃) or lithium tantalate (LiTaO₃) is used as the material of the waveguide substrate 10. Hereinafter, LiNbO₃ and LiTaO₃ may be respectively referred to as "LN" and "LT". A bonding interface 40 formed in a bonding step to be described below is included inside the waveguide substrate 10.

The intermediate layer 20 is provided on the support substrate 30, and is disposed between the waveguide substrate 10 and the support substrate 30. A low-refractive-index material for energy confinement is used as the material of the intermediate layer 20. The material preferably has a refractive index of 1.8 or less. For example, the material includes at least one of SiO₂, MgF₂, or CaF₂, and preferably SiO₂. Note that by using a substrate made of SiO₂, MgF₂, or CaF₂ as the support substrate 30, the intermediate layer 20 need not be provided when the support substrate 30 has a lower refractive index than the waveguide substrate 10.

The intermediate layer 20 may be formed by any appropriate method. For example, the intermediate layer 20 may be formed by physical vapor deposition such as sputtering, vacuum evaporation, or ion beam assisted deposition (IAD); chemical vapor deposition; or atomic layer deposition (ALD). For example, the forming of the intermediate layer 20 can be performed at a temperature ranging from room temperature (25°C) to 300°C.

The support substrate 30 supports the waveguide substrate 10. Any appropriate substrate may be used as the support substrate 30. The support substrate 30 may be a single crystalline body or a polycrystalline body. The support substrate 30 may also be a metal. The waveguide substrate 10 and the support substrate 30 are bonded to each other via the intermediate layer 20.

The material of which the support substrate 30 is made is preferably selected from the group consisting of silicon, sialon, sapphire, cordierite, mullite, glass, silica, quartz, alumina, SUS, iron-nickel alloy (42 alloy), MgF₂, CaF₂, and brass. The support substrate 30 has a thickness of, for example, 0.3 to 1 mm; however, any other appropriate thickness may be adopted.

The above silicon may be single-crystal silicon, polycrystalline silicon, or high-resistivity silicon. The support substrate 30 may be a silicon on insulator (SOI) substrate.

Typically, the above sialon is a ceramic obtained by sintering a mixture of silicon nitride and alumina, and has, for example, a composition represented by Si₆-wAlwOwN₈-w. Specifically, sialon has a composition in which alumina is mixed into silicon nitride, and w in the formula indicates the mixing ratio of alumina. w is preferably 0 or more and 4.2 or less, and more preferably 0.5 or more and 4.0 or less.

Typically, the above sapphire is a single crystalline body having a composition of Al₂O₃, and the above alumina is a polycrystalline body having a composition of Al₂O₃. The above alumina is preferably translucent alumina.

Typically, the above cordierite is a ceramic having a composition of 2MgO⋅2Al₂O₃⋅5SiO₂, and the above mullite is a ceramic having a composition in a range from 3Al₂O₃⋅2SiO₂ to 2Al₂O₃⋅SiO₂.

Although not shown in the drawings, the composite substrate 100 may further include any additional layer. The types and functions, number, combinations, arrangement, and the like of such layers may be appropriately set in accordance with the purpose thereof.

The composite substrate 100 may be manufactured in any appropriate shape. In one embodiment, the composite substrate 100 may be manufactured in the form of a so-called wafer. The size of the composite substrate 100 may be appropriately set depending on the purpose thereof, for example with a wafer (substrate) diameter of 50 mm to 150 mm.

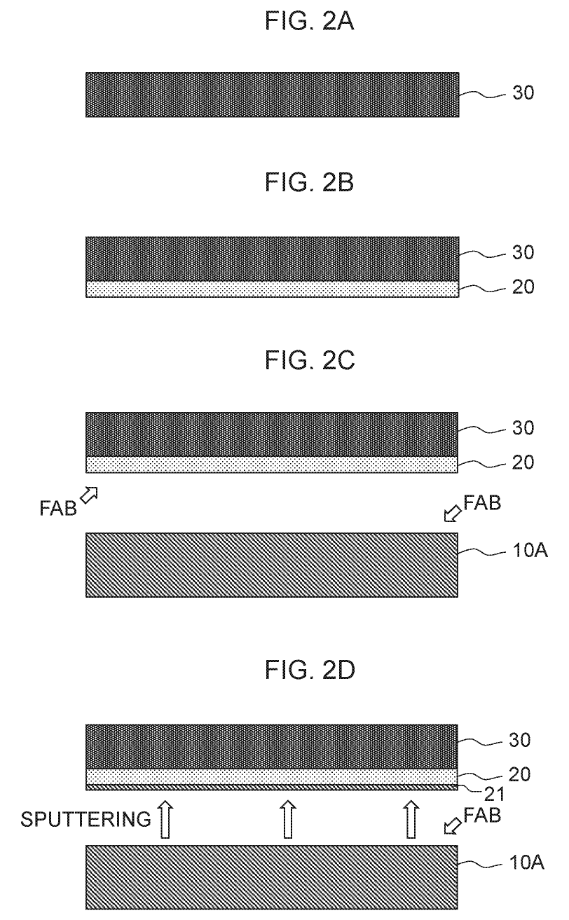

FIG. 2A to FIG. 4I are diagrams each showing an example of manufacturing steps of the composite substrate according to the first embodiment of the present invention.

FIG. 2A shows a preparation step among the manufacturing steps of the composite substrate 100. In this step, the support substrate 30 is prepared.

FIG. 2B shows a forming step of the intermediate layer 20 among the manufacturing steps of the composite substrate 100. In this step, the intermediate layer 20 is formed on a surface of the support substrate 30 prepared in the preparation step of FIG. 2A by, for example, forming an amorphous SiO₂ film with a predetermined thickness.

FIG. 2C shows an activation step among the manufacturing steps of the composite substrate 100. In this step, for example, an LN substrate 10A is prepared, which is a substrate having a predetermined thickness and is formed using LN as a material. Furthermore, an activation treatment is performed by irradiating each of a surface of the intermediate layer 20 formed on the surface of the support substrate 30 in the forming step of FIG. 2B and a surface of the LN substrate 10A with a fast atom beam (FAB) for a predetermined period of time using an inert gas such as Ar as atomic species. For example, the FAB irradiation period of time at this stage is preferably about 15 seconds. Note that an LT substrate can be used instead of the LN substrate as described above; however, "LN substrate 10A" is used to include the LT substrate in the following description.

FIG. 2D shows a sputtering step among the manufacturing steps of the composite substrate 100. In this step, regarding the FAB with which each of the intermediate layer 20 and the LN substrate 10A are irradiated in the activation step of FIG. 2C, the FAB irradiation on the intermediate layer 20 side is stopped and the FAB irradiation on the LN substrate 10A side is continued for an additional predetermined period of time. For example, the FAB irradiation period of time at this stage is about 3 to 10 minutes and preferably 4 to 7 minutes, when combined with the irradiation period of time in the activation step of FIG. 2C. Thus, LN of which the LN substrate 10A is made is sputtered and caused to adhere to the surface of the intermediate layer 20, and a sputtered film 21 made of the same material as the LN substrate 10A is formed on the intermediate layer 20 side.

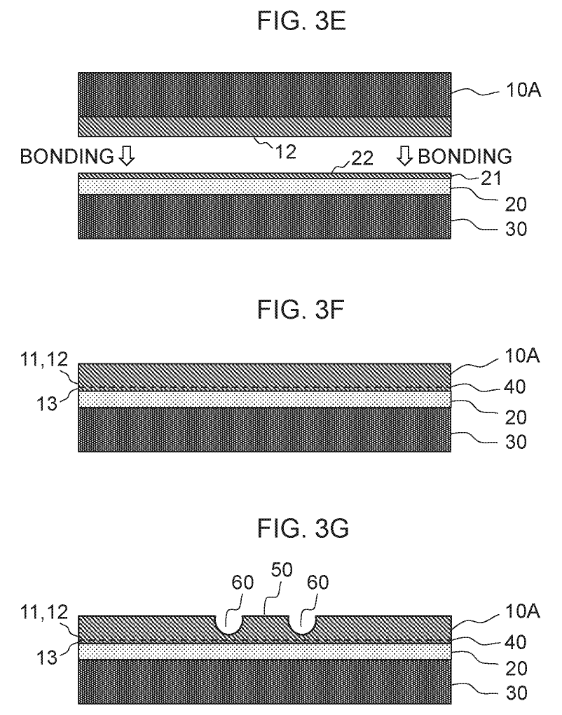

FIG. 3E shows the bonding step among the manufacturing steps of the composite substrate 100. In this step, the LN substrate 10A irradiated with the FAB in the activation step of FIG. 2C and the intermediate layer 20 on which the sputtered film 21 is formed in the sputtering step of FIG. 2D are bonded, thereby forming a bonded body thereof. Thus, the LN substrate 10A and the sputtered film 21 are bonded and integrated, and the bonding interface 40 therebetween is formed inside the LN substrate 10A. At this stage, three layers (a first layer 11, a second layer 12, and a third layer 13) are formed in the LN substrate 10A in the vicinity of the bonding interface 40 (see FIG. 3F). The first layer 11 is a layer that does not contain inert gas atoms such as Ar irradiated as the FAB in the activation step of FIG. 2C, and the second layer 12 is a layer that is disposed closer to the intermediate layer 20 than the first layer 11 and contains the above inert gas atoms. The third layer 13 is a layer that is disposed closer to the intermediate layer 20 than the first layer 11 and the second layer 12 and is in contact with the intermediate layer 20 for example, and does not contain the above inert gas atoms or contains the inert gas atoms at a lower content rate than the second layer 12. The first layer 11 is made of an LN or LT crystalline body being the material of the LN substrate 10A, and the third layer 13 is an amorphous film in which LN or LT has been amorphized. The second layer 12 is an LN or LT crystalline body similar to the first layer 11, or an amorphous film in which LN or LT has been amorphized, similar to the third layer 13. These layers may contain another atomic species mixed into the second layer 12, the third layer 13, or the like in the sputtering step of FIG. 2D, such as Fe atoms, Al atoms, or Cr atoms forming a jig, a pedestal part, or the like used to secure the LN substrate 10A. Details of these layers are described below. Note that in FIG. 3E and subsequent drawings, positional relationships between the LN substrate 10A, and the intermediate layer 20 and the support substrate 30 are shown upside down as compared with FIG. 2A to FIG. 2D.

FIG. 3F shows a thinning processing step among the manufacturing steps of the composite substrate 100. In this step, the LN substrate 10A of the bonded body after the bonding step shown in FIG. 3E is thinned by being polished to a predetermined thickness. For example, the LN substrate 10A can be thinned by being polished, by using a technique such as grinding, chemical mechanical polishing (CMP), or surface planarization using a gas cluster ion beam.

FIG. 3G shows a ridge processing step among the manufacturing steps of the composite substrate 100. In this step, the ridge portion 50 functioning as the optical waveguide is formed by providing the linear groove 60 at the two locations with the certain spacing therebetween on the surface of the LN substrate 10A thinned in the thinning processing step of FIG. 3F. For example, the grooves 60 can be formed by performing processing using laser light, dry etching such as reactive ion etching (RIE), or the like on the surface of the LN substrate 10A.

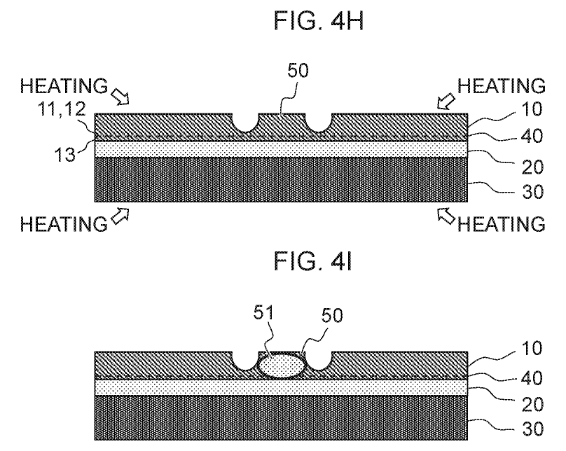

FIG. 4H shows a thermal annealing step among the manufacturing steps of the composite substrate 100. In this step, the bonded body in which the grooves 60 are formed on the surface of the LN substrate 10A by the ridge processing step of FIG. 3G is heated to a predetermined temperature. For example, the heating temperature at this stage is preferably about 300 to 450°C, and more preferably 400 to 450°C. Thus, in the composite substrate 100 manufactured from the bonded body, it is possible to improve optical propagation characteristics of the waveguide substrate 10 including the ridge portion 50 and to reduce optical loss when the ridge portion 50 is used as waveguide.

The inventors of the present invention have experimentally confirmed that the optical propagation characteristics are improved by the above thermal annealing step. As for the reason why the optical propagation characteristics of the waveguide substrate 10 are improved by the thermal annealing step, it is considered that, for example, part of the LN or LT in the waveguide substrate 10 that has been amorphized by the FAB irradiation during the activation step of FIG. 2C, the sputtering step of FIG. 2D, and the like recrystallizes by being heated.

Note that inert gas atoms and other atomic species mixed into the second layer 12, the third layer 13, and the like in the above-described sputtering step may diffuse into other layers when the LN substrate 10A is heated in the thermal annealing step of FIG. 4H, and the degree of this diffusion changes depending on heating temperature, heating period of time, and the like. That is, the content rates of Fe atoms, Al atoms, and Cr atoms in the first layer 11, the second layer 12, and the third layer 13 each differ depending on the heating temperature and the heating period of time in the thermal annealing step. In the second layer and the third layer, the content of Fe atoms is preferably 0.5 to 20 at%, the content of Al atoms is preferably 0.5 to 8.5 at%, and the content of Cr atoms is preferably 0.5 to 4.5 at%. The content of inert gas atoms of the second layer is preferably 2.5 to 3.5 at%, and the content of inert gas atoms of the third layer is preferably 0 to 1.1 at%.

Note that the thermal annealing step described above may be carried out at any time after the bonding step of FIG. 3E is carried out. For example, the thermal annealing step may be performed on the bonded body being the LN substrate 10A and the intermediate layer 20 obtained by the bonding step of FIG. 3E, after which the thinning processing step of FIG. 3F, the ridge processing step of FIG. 3G, or the like may be performed. Since the optical propagation characteristics of the waveguide substrate 10 are improved by carrying out an optical annealing step to be described below even without carrying out the thermal annealing step, the thermal annealing step may be performed as necessary or may be omitted.

FIG. 4I shows the optical annealing step among the manufacturing steps of the composite substrate 100. In this step, the grooves 60 are formed on the surface of the LN substrate 10A by the ridge processing step of FIG. 3G. Furthermore, in the bonded body on which the thermal annealing step of FIG. 4H is further performed as necessary, an irradiation range 51 corresponding to the ridge portion 50 sandwiched between the grooves 60 is set and this irradiation range 51 is irradiated with laser light in a surface direction (x-direction) of the composite substrate 100 formed by using the bonded body. An output and an irradiation period of time of the laser light are preferably 100 mW or more and 4 minutes or longer, respectively. Thus, the laser light is allowed to pass through the ridge portion 50 as the optical waveguide. Here, the irradiation range 51 need not necessarily be entirely within the ridge portion 50, and part of the irradiation range 51 may be outside the ridge portion 50.

In the present embodiment, by performing the above optical annealing step, it is possible to improve the optical propagation characteristics of the waveguide substrate 10 at the ridge portion 50 and to reduce optical loss in the composite substrate 100 manufactured from the bonded body. Note that the reason why the optical propagation characteristics of the waveguide substrate 10 are improved by the optical annealing step is described below.

Through each of the above steps, the composite substrate 100 having favorable optical propagation characteristics in the structure shown in FIGS. 1A and 1B is manufactured.

### Second Embodiment

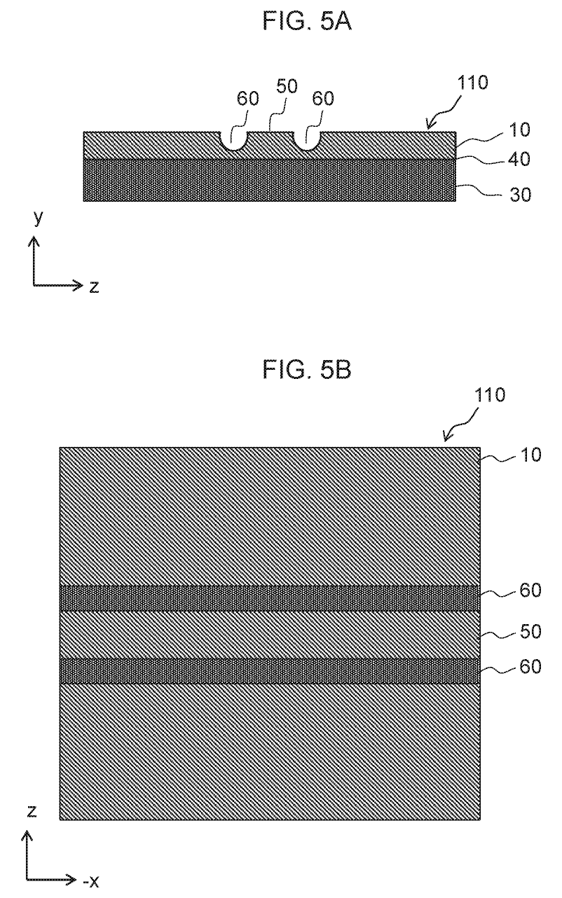

FIGS. 5A and 5B are diagrams showing a schematic configuration of a composite substrate according to a second embodiment of the present invention. A composite substrate 110 in the present embodiment has a structure in which the waveguide substrate 10 is bonded to the support substrate 30 without the intermediate layer 20, as compared with the composite substrate 100 of FIGS. 1A and 1B described in the first embodiment. FIG. 5A is a schematic cross-sectional view of the composite substrate 110, and FIG. 5B is a schematic plan view of the composite substrate 110. The x-, y-, and z-coordinate axes shown in FIGS. 5A and 5B are defined in accordance with the crystal axes of the waveguide substrate 10.

As described above, by using a substrate made of SiO₂, MgF₂, or CaF₂ as the support substrate 30, it is possible to form the composite substrate 110 that can be used as an optical element constituting an optical waveguide even without providing the intermediate layer 20 as in the structure shown in FIGS. 5A and 5B, when the support substrate 30 has a lower refractive index than the waveguide substrate 10.

Note that in the present embodiment as well, similar to the above-described first embodiment, the composite substrate 110 may further include any additional layer. The types and functions, number, combinations, arrangement, and the like of such layers may be appropriately set in accordance with the purpose thereof. The composite substrate 110 may be manufactured in any appropriate shape in accordance with the purpose thereof.

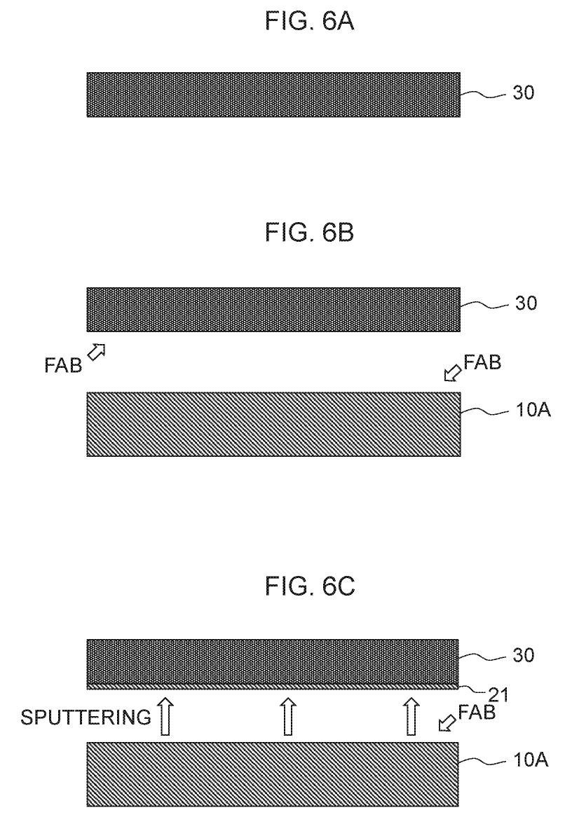

FIG. 6A to FIG. 8H are diagrams each showing an example of manufacturing steps of the composite substrate according to the second embodiment of the present invention.

FIG. 6A shows a preparation step among the manufacturing steps of the composite substrate 110. In this step, similar to the step of FIG. 2A described in the first embodiment, the support substrate 30 is prepared. Note that in the present embodiment, the step of forming the intermediate layer 20 on the support substrate 30 is omitted, in contrast to the first embodiment.

FIG. 6B shows an activation step among the manufacturing steps of the composite substrate 110. In this step, for example, the LN substrate 10A having the predetermined thickness is prepared. Furthermore, similar to the step of FIG. 2C described in the first embodiment, an activation treatment is performed by irradiating each of the surface of the support substrate 30 prepared in the preparation step of FIG. 6A and the surface of the LN substrate 10A with the FAB for the predetermined period of time using an inert gas such as Ar as atomic species.

FIG. 6C shows a sputtering step among the manufacturing steps of the composite substrate 110. In this step, similar to the step of FIG. 2D described in the first embodiment, regarding the FAB with which each of the support substrate 30 and the LN substrate 10A are irradiated in the activation step of FIG. 6B, the FAB irradiation on the support substrate 30 side is stopped and the FAB irradiation on the LN substrate 10A side is continued for the additional predetermined period of time. For example, the FAB irradiation period of time at this stage is about 3 to 10 minutes and preferably 4 to 7 minutes, when combined with the irradiation period of time in the activation step of FIG. 6B. Thus, LN of which the LN substrate 10A is made is sputtered and caused to adhere to the surface of the support substrate 30, and the sputtered film 21 made of the same material as the LN substrate 10A is formed on the support substrate 30 side.

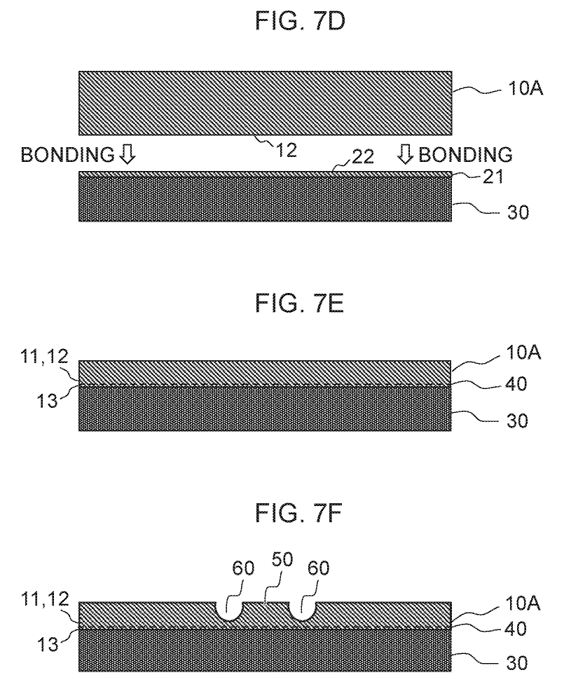

FIG. 7D shows a bonding step among the manufacturing steps of the composite substrate 110. In this step, similar to the step of FIG. 3E described in the first embodiment, the LN substrate 10A irradiated with the FAB in the activation step of FIG. 6B and the support substrate 30 on which the sputtered film 21 is formed in the sputtering step of FIG. 6C are bonded, thereby forming a bonded body thereof. Thus, the LN substrate 10A and the sputtered film 21 are bonded and integrated, and the bonding interface 40 therebetween is formed inside the LN substrate 10A. Note that in FIG. 7D and subsequent drawings, a positional relationship between the LN substrate 10A and the support substrate 30 is shown upside down as compared with FIG. 6A to FIG. 6C.

FIG. 7E shows a thinning processing step among the manufacturing steps of the composite substrate 110. In this step, similar to the step of FIG. 3F described in the first embodiment, the LN substrate 10A of the bonded body after the bonding step shown in FIG. 7D is thinned by being polished to the predetermined thickness.

FIG. 7F shows a ridge processing step among the manufacturing steps of the composite substrate 110. In this step, similar to the step of FIG. 3G described in the first embodiment, the ridge portion 50 functioning as the optical waveguide is formed by providing the linear groove 60 at the two locations with the certain spacing therebetween on the surface of the LN substrate 10A thinned in the thinning processing step of FIG. 7E.

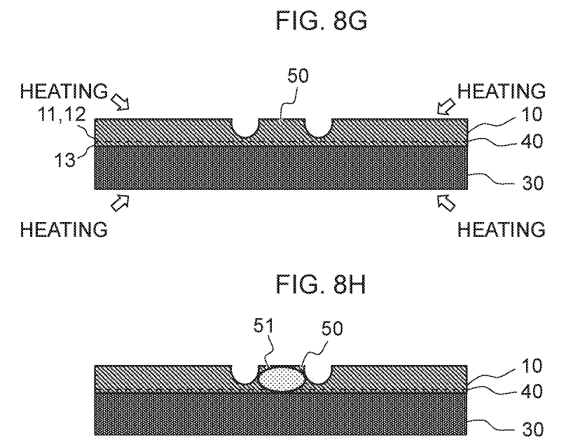

FIG. 8G shows a thermal annealing step among the manufacturing steps of the composite substrate 110. In this step, similar to the step of FIG. 4H described in the first embodiment, the bonded body in which the grooves 60 are formed on the surface of the LN substrate 10A by the ridge processing step of FIG. 7F is heated to the predetermined temperature. For example, the heating temperature at this stage is preferably about 300 to 450°C, and more preferably 400 to 450°C. Note that similar to the first embodiment, the thermal annealing step here too may be carried out at any time after the bonding step of FIG. 7D is carried out. For example, the thermal annealing step may be performed on the bonded body being the LN substrate 10A and the support substrate 30 obtained by the bonding step of FIG. 7D, after which the thinning processing step of FIG. 7E, the ridge processing step of FIG. 7F, or the like may be performed. The thermal annealing step may be performed as necessary or may be omitted.

FIG. 8H shows an optical annealing step among the manufacturing steps of the composite substrate 110. In this step, similar to the step of FIG. 4I described in the first embodiment, the grooves 60 are formed on the surface of the LN substrate 10A by the ridge processing step of FIG. 7F. Furthermore, in the bonded body on which the thermal annealing step of FIG. 8G is further performed as necessary, the irradiation range 51 corresponding to the ridge portion 50 sandwiched between the grooves 60 is set and this irradiation range 51 is irradiated with the laser light in the surface direction (x-direction) of the composite substrate 110 formed by using the bonded body. The output and the irradiation period of time of the laser light are preferably 100 mW or more and 4 minutes or longer, respectively. Thus, the laser light is allowed to pass through the ridge portion 50 as the optical waveguide. Furthermore, in the composite substrate 110 manufactured from the bonded body, the optical propagation characteristics of the waveguide substrate 10 at the ridge portion 50 are improved and optical loss is reduced.

Through each of the above steps, the composite substrate 110 having favorable optical propagation characteristics in the structure shown in FIGS. 5A and 5B is manufactured.

### Optical Annealing Step

Here, the reason why the optical propagation characteristics of the waveguide substrate 10 are improved by the optical annealing step described in FIG. 4I and FIG. 8H is presumed to be as follows. That is, in the optical annealing step, a crystal state of LN or LT of which the waveguide substrate 10 is made gradually changes due to energy from the incident laser light inside the ridge portion 50 upon irradiating the irradiation range 51 corresponding to the ridge portion 50 with the laser light. By maintaining this state for a predetermined period of time or longer, a crystal structure that facilitates transmittance of the laser light is formed inside the ridge portion 50, and it is considered that the optical propagation characteristics are improved more than before the irradiation with the laser light.

### Examples

Hereinafter, examples for verifying the effects of the optical annealing step according to the present invention are specifically described. Unless otherwise specified, the following procedures were performed at room temperature.

### Example 1

The bonded body was manufactured in accordance with the manufacturing steps described with reference to FIG. 2A to FIG. 3G. Specifically, the LN substrate 10A with a diameter of 4 inches and a thickness of 500 μm and a silicon substrate were prepared, and the silicon substrate was used as the support substrate 30. Then, the intermediate layer 20 was formed by forming an amorphous SiO₂ film with a thickness of 1.0 μm on the surface of the support substrate 30.

Next, after cleaning the surface of the LN substrate 10A and the surface of the support substrate 30 (on the intermediate layer 20 side), both substrates were placed into a vacuum chamber and evacuated to the order of 10⁻⁶ Pa, and the surfaces of both substrates were simultaneously irradiated for 15 seconds with a FAB using Ar gas (acceleration voltage 1 kV, Ar flow rate 27 sccm). Subsequently, the FAB irradiation on the support substrate 30 side was stopped, and the FAB irradiation on the LN substrate 10A side was continued for an additional 285 seconds (5 minutes in total). As a result, the sputtered film 21 with a thickness of 1.1 nm was formed on the surface of the support substrate 30 on the intermediate layer 20 side.

Next, the LN substrate 10A and the support substrate 30 were directly bonded. Specifically, the beam-irradiated surfaces of both substrates were overlapped, and both substrates were bonded by a pressure being applied thereto at 10,000 N at room temperature for 2 minutes, thereby obtaining the bonded body.

Next, after polishing the surface of the LN substrate 10A of the obtained bonded body to a thickness of 3.6 μm, two groove 60 with a depth of 2 μm and a spacing of 6 μm therebetween were formed on the surface of the LN substrate 10A by further performing ridge processing using laser light. Subsequently, by cutting the bonded body after the ridge processing to a predetermined size and polishing the cut end surfaces, a bonded body having an x-direction length of 1.4 mm and a z-direction length of 8.5 mm, including the ridge portion 50 with a width of 6 μm and a height of 2 μm as an optical waveguide, and having the same structure as the composite substrate 100 shown in FIGS. 1A and 1B was formed.

Next, thermal annealing was performed by placing the obtained bonded body in a high-temperature furnace, raising the temperature thereof from room temperature to 450°C and maintaining this temperature for a certain period of time, and then returning the temperature to room temperature. In the following step, this bonded body after the thermal annealing was used as the composite substrate 100 for optical annealing.

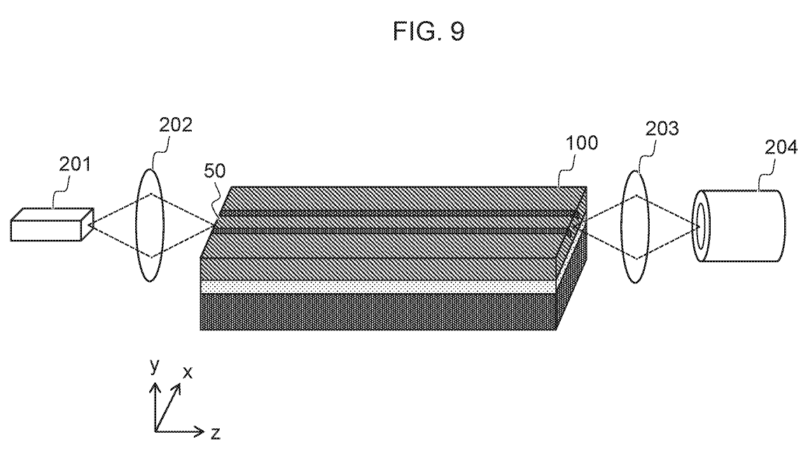

Next, in a characteristics evaluation system of the composite substrate 100 shown in FIG. 9, laser light output from a laser 201 (output intensity: 150 mW; wavelength: 976 nm) was focused by an incident lens 202 and the composite substrate 100 to be optically annealed (the bonded body after the thermal annealing) was irradiated with the laser light. Furthermore, the irradiation range 51 of the laser light was caused to substantially coincide with a cross section of the ridge portion 50 (see FIG. 4I) by finely adjusting a position of the composite substrate 100 using a stage or the like, thereby allowing the laser light with which the irradiation range 51 was irradiated in the surface direction of the composite substrate 100 to pass through the inside of the ridge portion 50. Note that in FIG. 9, the axes of the characteristics evaluation system are defined such that a propagation direction of the laser light in the ridge portion 50, that is, an extension direction of the ridge portion 50 along the surface direction of the composite substrate 100 is set as the z-axis. This definition of the axial direction differs from the direction of the crystal axis of the waveguide path substrate 10 shown in FIGS. 1A and 1B, or FIGS. 5A and 5B. At this stage, an incident angle of the laser light on the composite substrate 100 is preferably offset by a predetermined angle from a direction in which the laser light propagates in the ridge portion 50 (z-direction), in order to prevent reflected light from returning to the laser 201 when the laser light is incident on the ridge portion 50. For example, in the composite substrate 100, an angle between an end surface of the ridge portion 50 (an incident surface of the laser light) and a side surface is formed at 84 degrees, and the laser light is irradiated such that the laser light refracted at this end surface propagates in the z-direction in the ridge portion 50. Thus, it is possible to cause the laser light to propagate in the z-direction in the ridge portion 50 while preventing the reflected light from returning to the laser 201. In addition, if the incident angle of the laser light on the end surface of the ridge portion 50 is a predetermined angle offset from 90 degrees (for example, 84 degrees), the composite substrate 100 can be irradiated with the laser light from any direction. However, in the following description, even if the irradiation direction of the laser light relative to the end surface of the ridge portion 50 is inclined in any direction, the irradiation direction is referred to as the surface direction of the composite substrate 100 if the laser light with which the composite substrate 100 is irradiated in this irradiation direction can propagate along the extension direction of the ridge portion 50.

As described above, when the laser light was incident on the ridge portion 50, the laser light passing through the ridge portion 50 and output from an opposite surface was focused by an exit lens 203 and input to a measurement instrument 204, and the intensity of the laser light received by the measurement instrument 204 was continuously measured. As a result, a measured value of 63.4 mW was obtained at the start of the measurement. Furthermore, the measured value gradually changed as the measurement period of time elapsed, and increased to 65.8 mW after 4 minutes. Note that almost no change was observed in the measured value thereafter.

### Example 2

Thermal annealing was performed by placing the bonded body obtained using a similar method as in Example 1 in a high-temperature furnace, raising the temperature thereof from room temperature to a lower temperature than in Example 1 (300°C) and maintaining this temperature for a certain period of time, and then returning the temperature to room temperature. In the following step, this bonded body after the thermal annealing was used as the composite substrate 100 for optical annealing.

Subsequently, similarly to Example 1, in the characteristics evaluation system shown in FIG. 9, the laser light output from the laser 201 (output intensity: 150 mW; wavelength: 976 nm) was focused by the incident lens 202 and this irradiation range 51 was caused to substantially coincide with the cross section of the ridge portion 50, thereby allowing the laser light to pass through the inside of the ridge portion 50. Then, the laser light passing through the ridge portion 50 and output from the opposite surface was focused by the exit lens 203 and input to the measurement instrument 204, and the intensity of the laser light received by the measurement instrument 204 was continuously measured. As a result, while a measured value of 34.6 mW was obtained at the start of the measurement, the measured value gradually changed as the measurement period of time elapsed and increased to 34.85 mW after 4.5 minutes. Note that almost no change was observed in the measured value thereafter.

According to Example 2 described above, it was confirmed that when the temperature of the thermal annealing is lower than in Example 1, the improvement effect on the optical propagation characteristics by the optical annealing performed thereafter is reduced.

### Example 3

Thermal annealing was performed by placing the bonded body obtained using a similar method as in Examples 1 and 2 in a high-temperature furnace, raising the temperature thereof from room temperature to 450°C and maintaining this temperature for a certain period of time, and then returning the temperature to room temperature. In the following step, this bonded body after the thermal annealing was used as the composite substrate 100 for optical annealing.

Subsequently, similarly to Examples 1 and 2, in the characteristics evaluation system shown in FIG. 9, the laser light output from the laser 201 (output intensity: 100 mW; wavelength: 976 nm) was focused by the incident lens 202 and this irradiation range 51 was caused to substantially coincide with the cross section of the ridge portion 50, thereby allowing the laser light to pass through the inside of the ridge portion 50. Then, the laser light passing through the ridge portion 50 and output from the opposite surface was focused by the exit lens 203 and input to the measurement instrument 204, and the intensity of the laser light received by the measurement instrument 204 was continuously measured. As a result, while a measured value of 41.2 mW was obtained at the start of the measurement, the measured value gradually changed as the measurement period of time elapsed, increased to 41.6 mW after 4 minutes, and subsequently increased to 41.65 mW after 6 minutes.

According to Example 3 described above, it was confirmed that when the intensity of the laser light is lower than in Example 1, the improvement effect on the optical propagation characteristics by the optical annealing is reduced and the time until the improvement effect reaches a plateau is long.

### Example 4

For the composite substrate 100 used in Example 3, the output intensity of the laser light in the characteristics evaluation system shown in FIG. 9 was changed from 100 mW to 200 mW and the measurement by the measurement instrument 204 was continued. At this stage, while a measured value of 85.5 mW was obtained immediately after the change in the output intensity of the laser light, the measured value changed little even as the measurement period of time elapsed and increased slightly to 85.55 mW after 5 minutes.

Furthermore, the output intensity of the laser light was changed from 200 mW to 150 mW, and the measurement by the measurement instrument 204 was continued. At this stage, a measured value of 64.1 mW was obtained, and the measured value did not change even after five minutes had elapsed.

Furthermore, the output intensity of the laser light was changed from 150 mW to 100 mW, and the measurement by the measurement instrument 204 was continued. At this stage, a measured value of 43.2 mW was obtained, and the measured value did not change even after five minutes had elapsed.

According to Example 4 described above, it was confirmed that when the improvement effect on the optical propagation characteristics by the irradiation with the laser light reaches a plateau, the optical propagation characteristics do not change even if the output intensity of the laser light is subsequently changed.

According to the embodiments of the present invention described above, the following advantageous effects are achieved.

(1) A manufacturing method for the composite substrate 100 includes: the forming step (FIG. 2B) of forming the intermediate layer 20 containing at least one of SiO₂, MgF₂, or CaF₂ on the support substrate 30; the activation step (FIG. 2C) of irradiating, with the FAB, each of the surface of the piezoelectric material substrate (the LN substrate 10A) formed using LN (or LT) as a material and the surface of the intermediate layer 20 formed on the support substrate 30; the sputtering step (FIG. 2D) of further irradiating the surface of the LN substrate 10A with the FAB, and forming the sputtered film 21 containing the material of the LN substrate 10A on the surface of the intermediate layer 20; the bonding step (FIG. 3E) of obtaining the bonded body by bonding the LN substrate 10A and the intermediate layer 20 on which the sputtered film 21 is formed; and the optical annealing step (FIG. 4I) of irradiating this bonded body with the laser light in the surface direction of the composite substrate 100, wherein the composite substrate 100 is formed using the bonded body irradiated with the laser light in the optical annealing step. By doing so, it is possible to realize the manufacturing method for the composite substrate 100 that enhances bonding strength between the intermediate layer 20 provided on the support substrate 30 and the piezoelectric material substrate, and that enables the composite substrate 100 to exhibit favorable optical propagation characteristics, even when the piezoelectric material substrate is directly bonded to the intermediate layer 20 without providing another layer.

(2) A manufacturing method for the composite substrate 110 includes: the activation step (FIG. 6B) of irradiating, with the FAB, each of the surface of the LN substrate 10A formed using LN (or LT) as a material and the surface of the support substrate 30 containing SiO₂, MgF₂, or CaF₂; the sputtering step (FIG. 6C) of further irradiating the surface of the LN substrate 10A with the FAB, and forming the sputtered film 21 made of the material of the LN substrate 10A on the surface of the support substrate 30; the bonding step (FIG. 7D) of obtaining the bonded body by bonding the LN substrate 10A and the support substrate 30 on which the sputtered film 21 is formed; and the optical annealing step (FIG. 8H) of irradiating this bonded body with the laser light in the surface direction of the composite substrate 110, wherein the composite substrate 110 is formed using the bonded body irradiated with the laser light in the optical annealing step. By doing so, it is possible to realize the manufacturing method for the composite substrate 110 that enhances bonding strength between the support substrate 30 and the piezoelectric material substrate, and that enables the composite substrate 110 to exhibit favorable optical propagation characteristics, even when the piezoelectric material substrate is directly bonded to the support substrate 30 without providing another layer.

(3) The manufacturing methods for the composite substrates 100 and 110 further include the thermal annealing step (FIG. 4H, FIG. 8G) of heating the bonded body to the predetermined temperature. In the optical annealing step of irradiating the bonded body with the laser light, this bonded body after being heated to the predetermined temperature in the thermal annealing step may be irradiated with the laser light. By doing so, since the bonding strength between the piezoelectric material substrate and the intermediate layer 20, the support substrate 30, or the like can be further enhanced, it is possible to reliably prevent peeling of these bonds in the thinning processing step, the ridge processing step, and the like performed before the optical annealing step.

(4) The manufacturing methods for the composite substrates 100 and 110 further include the ridge processing step of forming the ridge portion 50 on the LN substrate 10A of the bonded body. In the optical annealing step of irradiating the bonded body with the laser light, the irradiation range 51 corresponding to the ridge portion 50 is preferably set and this irradiation range 51 is preferably irradiated with the laser light. By doing so, in the composite substrates 100 and 110, it is possible to obtain the ridge portion 50 that can be used as the optical waveguide having favorable optical propagation characteristics.

(5) In the optical annealing step of irradiating the bonded body with the laser light, the bonded body used for manufacturing the composite substrates 100 and 110 is preferably irradiated with the laser light for 4 minutes or longer. This bonded body is preferably irradiated with the laser light having at an output of 100 mW or more. By doing so, in the composite substrates 100 and 110, it is possible to reliably obtain favorable optical propagation characteristics.

Note that the present invention is not limited to the above embodiments, and can be implemented using any components without departing from the scope thereof.

The above embodiments, variations, and the like are merely examples, and the present invention is not limited to thereto so long as the features of the invention are not impaired. Although various embodiments, variations, and the like have been described above, the present invention is not limited thereto. Other aspects conceivable within the scope of the technical idea of the present invention are also included within the scope of the present invention.

What is claimed is:

1. A manufacturing method for a composite substrate, the manufacturing method comprising:
a step of forming an intermediate layer containing at least one of SiO₂, MgF₂, or CaF₂ on a support substrate;
a step of irradiating, with a fast atom beam, each of a surface of a piezoelectric material substrate formed using LN or LT as a material and a surface of the intermediate layer formed on the support substrate;
a step of further irradiating the surface of the piezoelectric material substrate with the fast atom beam, and forming a sputtered film containing the material of the piezoelectric material substrate on the surface of the intermediate layer;
a step of obtaining a bonded body by bonding the piezoelectric material substrate and the intermediate layer on which the sputtered film is formed; and
a step of irradiating the bonded body with laser light in a surface direction of the composite substrate, wherein
the composite substrate is formed using the bonded body irradiated with the laser light.

2. A manufacturing method for a composite substrate, the manufacturing method comprising:
a step of irradiating, with a fast atom beam, each of a surface of a piezoelectric material substrate formed using LN or LT as a material and a surface of a support substrate containing SiO₂, MgF₂, or CaF₂;
a step of further irradiating the surface of the piezoelectric material substrate with the fast atom beam, and forming a sputtered film made of the material of the piezoelectric material substrate on the surface of the support substrate;
a step of obtaining a bonded body by bonding the piezoelectric material substrate and the support substrate on which the sputtered film is formed; and
a step of irradiating the bonded body with laser light in a surface direction of the composite substrate, wherein
the composite substrate is formed using the bonded body irradiated with the laser light.

3. The manufacturing method for the composite substrate according to claim 1, the manufacturing method further comprising a step of heating the bonded body to a predetermined temperature, wherein
in the step of irradiating the bonded body with the laser light, the bonded body is irradiated with the laser light after being heated to the predetermined temperature.

4. The manufacturing method for the composite substrate according to claim 2, the manufacturing method further comprising a step of heating the bonded body to a predetermined temperature, wherein
in the step of irradiating the bonded body with the laser light, the bonded body is irradiated with the laser light after being heated to the predetermined temperature.

5. The manufacturing method for the composite substrate according to claim 1, the manufacturing method further comprising a step of forming a ridge portion on the piezoelectric material substrate of the bonded body, wherein
in the step of irradiating the bonded body with the laser light, an irradiation range corresponding to the ridge portion is set and the irradiation range is irradiated with the laser light.

6. The manufacturing method for the composite substrate according to claim 2, the manufacturing method further comprising a step of forming a ridge portion on the piezoelectric material substrate of the bonded body, wherein
in the step of irradiating the bonded body with the laser light, an irradiation range corresponding to the ridge portion is set and the irradiation range is irradiated with the laser light.

7. The manufacturing method for the composite substrate according to claim 1, wherein
in the step of irradiating the bonded body with the laser light, the bonded body is irradiated with the laser light for 4 minutes or longer.

8. The manufacturing method for the composite substrate according to claim 2, wherein
in the step of irradiating the bonded body with the laser light, the bonded body is irradiated with the laser light for 4 minutes or longer.

9. The manufacturing method for the composite substrate according to claim 1, wherein
in the step of irradiating the bonded body with the laser light, the bonded body is irradiated with the laser light at an output of 100 mW or more.

10. The manufacturing method for the composite substrate according to claim 2, wherein
in the step of irradiating the bonded body with the laser light, the bonded body is irradiated with the laser light at an output of 100 mW or more.
